(19) United States
(12) Patent Application Publication
(10) Pub. No.: US 2025/0107235 A1
(43) Pub. Date: Mar. 27, 2025

(54) ARRAY SUBSTRATE AND DISPLAY DEVICE

(71) Applicant: Sharp Display Technology Corporation, Kameyama City (JP)

(72) Inventors: Seiichi UCHIDA, Kameyama City (JP); Kuniaki OKADA, Kameyama City (JP)

(21) Appl. No.: 18/783,476

(22) Filed: Jul. 25, 2024

(30) Foreign Application Priority Data
Sep. 25, 2023 (JP) 2023-159987

(51) Int. Cl. H01L 27/12; G02F 1/1343; G02F 1/1362

(52) U.S. Cl. CPC H10D 86/60; G02F 1/134372; G02F 1/136209; G02F 1/136286; H10D 86/441; H10D 86/421

(57) ABSTRACT

An array substrate includes a first line, a second line crossing the first line, a semiconductor section made of semiconductor material, extending to cross the first line, and including a first end portion overlapping the second line and a second end portion, a first insulation film between the first line and the semiconductor section, a first electrode being a portion of the first line and overlapping the semiconductor section via the first insulation film, a second electrode being a portion of the second line and overlapping the semiconductor section and being connected to the semiconductor section, and a third electrode disposed to overlap the second end portion of the semiconductor section and connected to the semiconductor section. The semiconductor section includes a resistance lowered section not overlapping the first electrode and a first overlapping portion overlapping a portion of the first electrode and a portion of the second line.

### CROSS REFERENCE TO RELATED APPLICATION

This application claims priority from Japanese Patent Application No. 2023-159987 filed on Sep. 25, 2023. The entire contents of the priority application are incorporated herein by reference.

### TECHNICAL FIELD

The present technology described herein relates to an array substrate and a display device.

### BACKGROUND

An example of known display devices includes thin film transistors of a bottom gate structure including an oxide semiconductor layer. In such a thin film transistor, an oxide insulating layer is formed as a channel protection layer that is in contact with a part of the oxide semiconductor layer overlapping a gate electrode layer, and an oxide insulating layer is formed to cover a peripheral portion (including a side surface) of the stacked oxide semiconductor layer when forming the oxide insulating layer. A source electrode layer and a drain electrode layer are formed so as not to overlap the channel protecting layer, and an insulating layer disposed on the source electrode layer and the drain electrode layer is in contact with the oxide semiconductor layer.

In the display device described above, a high resistance source section of the oxide semiconductor layer is connected to a portion branched from the source line and the oxide semiconductor layer does not overlap the source line. The high resistance source section of the oxide semiconductor layer has a same potential as the source line. Therefore, the parasitic capacitance created between the high resistance source section and other electrodes or lines is likely to be large. Due to such a large parasitic capacitance, the load on the source line becomes quite high.

### SUMMARY

The technology described herein was made in view of the above circumstances. An object is to reduce a load on a second line.

(1) An array substrate according to the technology described herein includes a first line, a second line that crosses the first line, a semiconductor section being made of semiconductor material, extending to cross the first line, and including a first end portion that overlaps the second line and a second end portion, a first insulation film disposed between the first line and the semiconductor section, a first electrode that is a portion of the first line and overlaps the semiconductor section via the first insulation film, a second electrode that is a portion of the second line and overlaps the semiconductor section and is connected to the semiconductor section, and a third electrode that is disposed to overlap the second end portion of the semiconductor section and connected to the semiconductor section. The semiconductor section includes a resistance lowered section that does not overlap the first electrode and in which resistance is lowered. The semiconductor section includes a first overlapping portion that overlaps a portion of the first electrode and a portion of the second line.

(2) In the array substrate, in addition to (1), the semiconductor section may include a first extending portion that extends in an oblique direction with respect to the first line and the second line and crosses the first line, and the first overlapping portion may be a portion of the first extending portion.

(3) In the array substrate, in addition to (2), the semiconductor section may include a second extending portion that includes the first end portion of the semiconductor section and extends parallel to the second line, and the second extending portion may be continuous to the first extending portion and overlap the second line.

(4) In the array substrate, in addition to (2) or (3), the resistance lowered section of the semiconductor section may include a portion that ranges from the second end portion to the first line and not overlap the second line.

(5) In the array substrate, in addition to (1), the semiconductor section may include a third extending portion that extends along the second line and overlaps the second line and crosses the first line, and the first overlapping portion may be a portion of the third extending portion.

(6) The array substrate may further include, in addition to (5), a first light blocking portion that extends along the first line and overlaps the first line and is wider than the first line. The first light blocking portion may include a second overlapping portion that does not overlap the first line and overlaps a portion of the third extending portion.

(7) A display device according to the technology described herein includes the array substrate of any one of (1) to (6) and an opposed substrate disposed to opposite the array substrate.

According to the technology described herein, a load on the second line can be reduced.

### BRIEF DESCRIPTION OF THE DRAWINGS

FIG. 1 is a general perspective view illustrating a head-mounted display that is mounted on a head of a user according to a first embodiment.

FIG. 2 is a general side view illustrating an optical relation of a liquid crystal display device and a lens that are included in a head mounting device of the head-mounted display according to the first embodiment and an eyeball of the user.

FIG. 3 is a plan view illustrating a liquid crystal panel and a flexible substrate included in the liquid crystal display device according to the first embodiment.

FIG. 4 is a cross-sectional view of the liquid crystal panel according to the first embodiment.

FIG. is a plan view illustrating a pixel arrangement in the display area of the array substrate included in the liquid crystal panel according to the first embodiment.

FIG. 6 is a cross-sectional view the liquid crystal panel according to the first embodiment taken along line vi-vi in FIG. 5.

FIG. 7 is a cross-sectional view of the liquid crystal panel according to the first embodiment taken along line vii-vii in FIG. 5.

FIG. 8 is a plan view illustrating a pixel in the display area of the liquid crystal panel according to the first embodiment and illustrating configurations of a first metal film and a fourth metal film with shading.

FIG. 9 is a plan view illustrating a pixel in the display area of the liquid crystal panel according to the first embodiment and illustrating configurations of a semiconductor film and a second metal film with shading.

FIG. 10 is a plan view illustrating a pixel in the display area of the liquid crystal panel according to the first embodiment and illustrating first overlapping portions with shading.

FIG. 11 is a plan view illustrating a pixel of Comparative Example 1 of Comparative Experiment 1 according to the first embodiment and configurations of a semiconductor film and a second metal film with shading.

FIG. 12 is a table illustrating experimental results of Comparative Experiment 1 according to the first embodiment.

FIG. 13 is a cross-sectional view of a liquid crystal panel according to a second embodiment taken along the same line as FIG. 6.

FIG. 14 is a cross-sectional view of the liquid crystal panel according to the second embodiment taken along the same line as FIG. 7.

FIG. 15 is a plan view illustrating a pixel in a display area of a liquid crystal panel according to a third embodiment and illustrating configurations of a semiconductor film and a second metal film with shading.

FIG. 16 is a plan view illustrating a pixel in the display area of the liquid crystal panel according to the third embodiment and illustrating first overlapping portions and second overlapping portions with shading.

FIG. 17 is a table illustrating experimental results of Comparative Experiment 2 according to the third embodiment.

### DETAILED DESCRIPTION

### First Embodiment

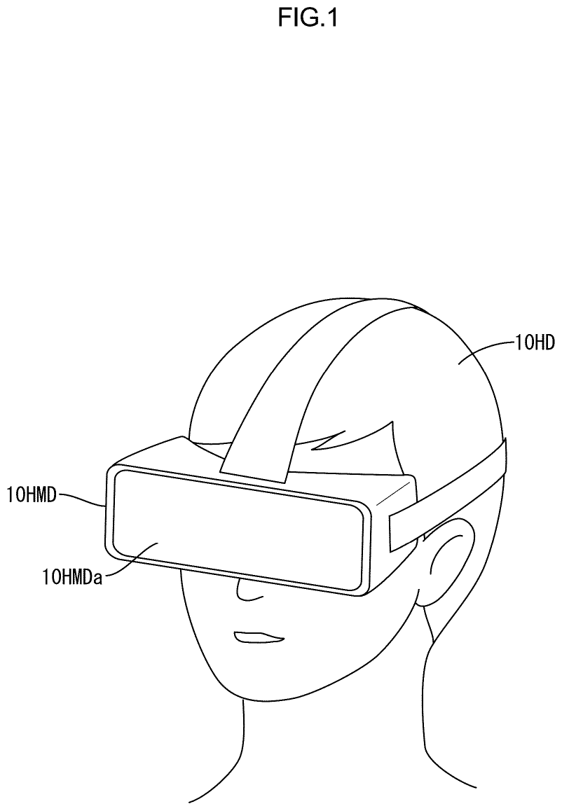

A first embodiment will be described with reference to FIGS. 1 to 12. In this embodiment section, a goggle-type head-mounted display (HMD) 10HMD and a liquid crystal display device 10 (a display device) used therein will be described as an example. X-axis, Y-axis and Z-axis may be present in the drawings and each of the axial directions represents a direction represented in each drawing.

An outer appearance of the goggle-type head-mounted display 10HMD will be described with reference to FIG. 1. As illustrated in FIG. 1, the goggle-type head-mounted display 10HMD includes a head mounting device 10HMDa that is mounted on the head 10HD of the user. The head mounting device 10HMDa covers both eyes of the user.

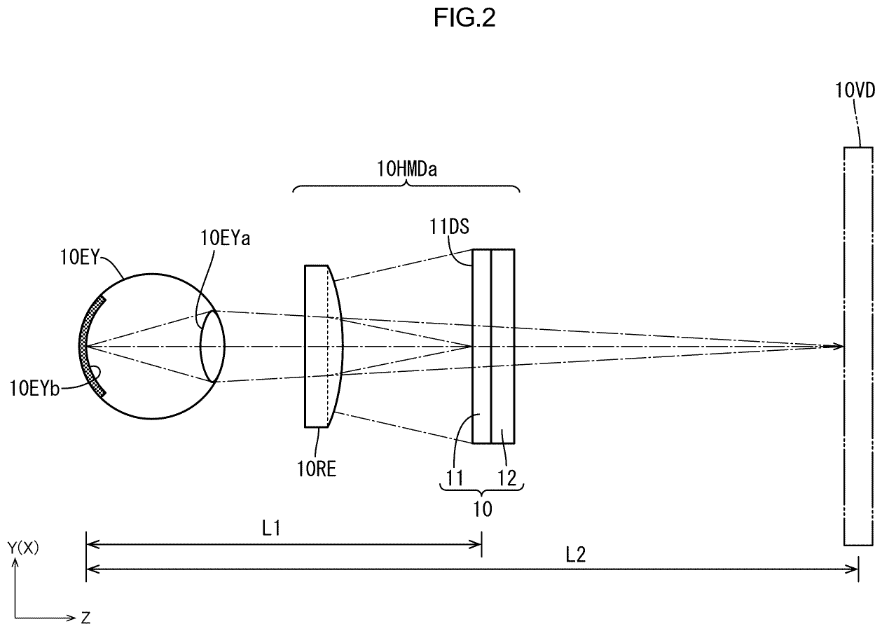

A configuration of the head mounting device 10HMDa will be described with reference to FIG. 2. As illustrated in FIG. 2, the head mounting device 10HMDa at least includes the liquid crystal display device 10 displaying images thereon and a lens 10RE with which the images displayed on the liquid crystal display device 10 are formed (imaging) on the eyeballs EY of the user. The liquid crystal display device 10 at least includes a liquid crystal panel 11 (a display device) and a backlight 12 (a lighting device) that supplies light to the liquid crystal panel 11. The liquid crystal panel 11 includes a plate surface that is opposed to the lens 10RE as a display surface 11DS on which images are displayed. The lens 10RE is disposed between the liquid crystal display device 10 and the eyeballs 10EY of the user and makes the light rays transmitting therethrough to be refracted. By adjusting a focal distance of the lens 10RE, images formed on the retina (eye) 10EYb through the crystalline lens 10EYa of the eyeball 10EY can be seen by a user as if the images are displayed on a virtual display 10VD that is present in appearance at a position away from the eyeball 10EY by a distance L2. The distance L2 is much greater than an actual distance L1 from the eyeball 10EY to the liquid crystal display device 10. Accordingly, the user sees a magnified image (a virtual image) displayed on the virtual display 10VD having a screen size (for example, from dozens of inches to several hundred inches) much greater than the screen size (for example, from several numbers of 0.1 inches to several inches) of the liquid crystal display device 10.

One liquid crystal display device 10 may be mounted in the head mounting device 10HMDa and images for a right eye and images for a left eye may be displayed on the liquid crystal display device 10. Two liquid crystal display devices 10 may be mounted in the head mounting device 10HMDa and images for a right eye may be displayed on one of the two liquid crystal display devices 10 and images for a left eye may be displayed on the other one of the two liquid crystal display devices 10. The head mounting device 10HMDa may include earphone that is put on user's ears and through which sounds are output.

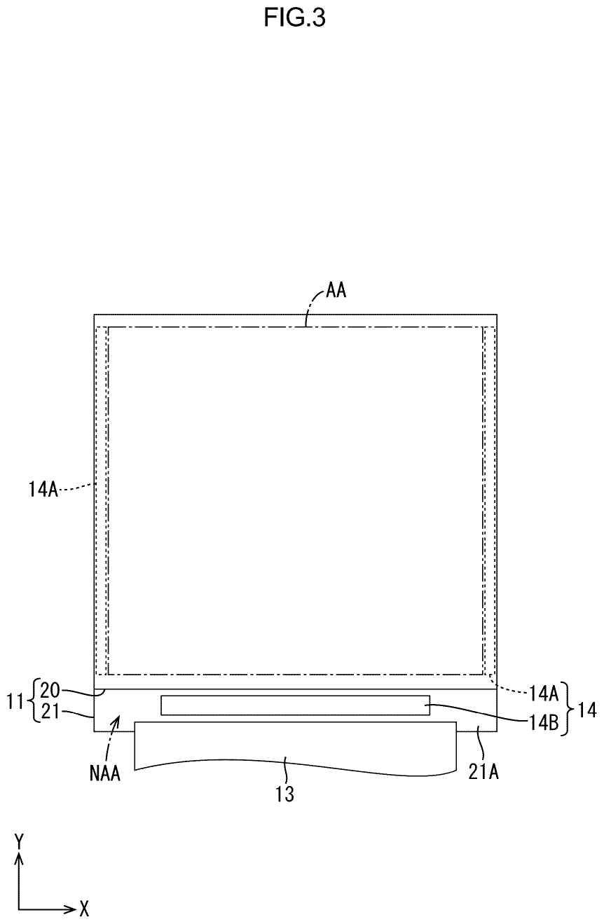

A configuration of the liquid crystal panel 11 included in the liquid crystal display device 10 will be described with reference to FIG. 3. The backlight 12 has a known configuration and includes a light source such as LEDs and optical members for converting the light from the light source into planar light by adding optical effects to the light from the light source. As illustrated in FIG. 3, the liquid crystal panel 11 has a rectangular plan view shape as a whole. A middle section of a screen of the liquid crystal panel 11 is configured as a display area AA in which images are displayed. An outer section in a frame shape surrounding the display area AA in the screen of the liquid crystal panel 11 is configured as a non-display area NAA in which images are not displayed. In FIG. 3, an area defined by a chain line is the display area AA. The liquid crystal panel 11 of this embodiment, which is used for the head-mounted display 10HMD, has quite high precision and the pixel density is about 1000 ppi or higher.

As illustrated in FIG. 3, the liquid crystal panel 11 includes a pair of substrates 20, 21 that are bonded to each other. One of the substrates 20, 21 on the front side is an opposed substrate 20 (a second substrate, a CF substrate) and another one on the back side is an array substrate 21 (a first substrate, an active matrix substrate). The opposed substrate 20 and the array substrate 21 include substantially transparent glass substrates 20GS, 21GS having high light transmissive properties and various films formed in layers on inner sides of the glass substrates 20GS, 21GS. The glass substrate 20GS, 21Gs includes alkali-free glass as main material. The array substrate 21 is larger than the opposed substrate 20. A projecting portion 21A, which is an edge portion of the array substrate 21, projects from a corresponding edge of the opposed substrate 20. A flexible board 13 is mounted on the projecting portion 21A of the array substrate 21. The flexible board 13 includes a substrate having insulating properties and flexibility and multiple traces formed on the substrate. One edge of the flexible board 13 is connected to the array substrate 21 and other edge of the flexible board 13 is connected to an external control board (a signal supply). Various kinds of signals supplied from the control board are transferred to the liquid crystal panel 11 via the flexible board 13.

As illustrated in FIG. 3, a circuit 14 (a surrounding circuit) is mounted on the non-display area NAA of the liquid crystal panel 11. The circuit 14 includes a pair of first circuits 14A and a second circuit 14B. The pair of first circuits 14A are disposed to sandwich the display area AA with respect to the X-axis direction. The first circuit 14A is disposed in a belt-shaped area extending along the Y-axis direction. The first circuits 14A are for supplying scan signals to gate lines 25, which will be described later, and are monolithically fabricated on the array substrate 21. The first circuit 14A is a gate driver monolithic (GDM) circuit. The first circuit 14A includes a shift resistor circuit that is configured to output scan signals at predetermined timing and a buffer circuit that is configured to amplify scan signals. The second circuit 14B is disposed in an area between the display area AA and the flexible board 13 with respect to the Y-axis direction. The second circuit 14B is disposed in a belt-shaped area extending along the X-axis direction. The second circuit 14B is for supplying image signals (data signals) to source lines 26, which will be described later, and is monolithically fabricated on the array substrate 21. The second circuit 14B includes a source shared driving (SSD) circuit. The second circuit 14B is configured as a switching component that distributes the image signals supplied from the flexible board 13 to the source lines 26.

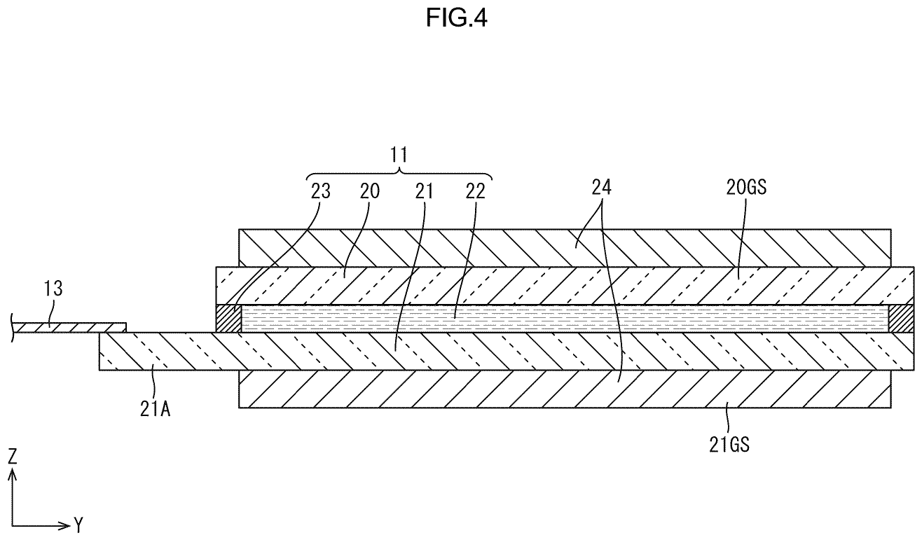

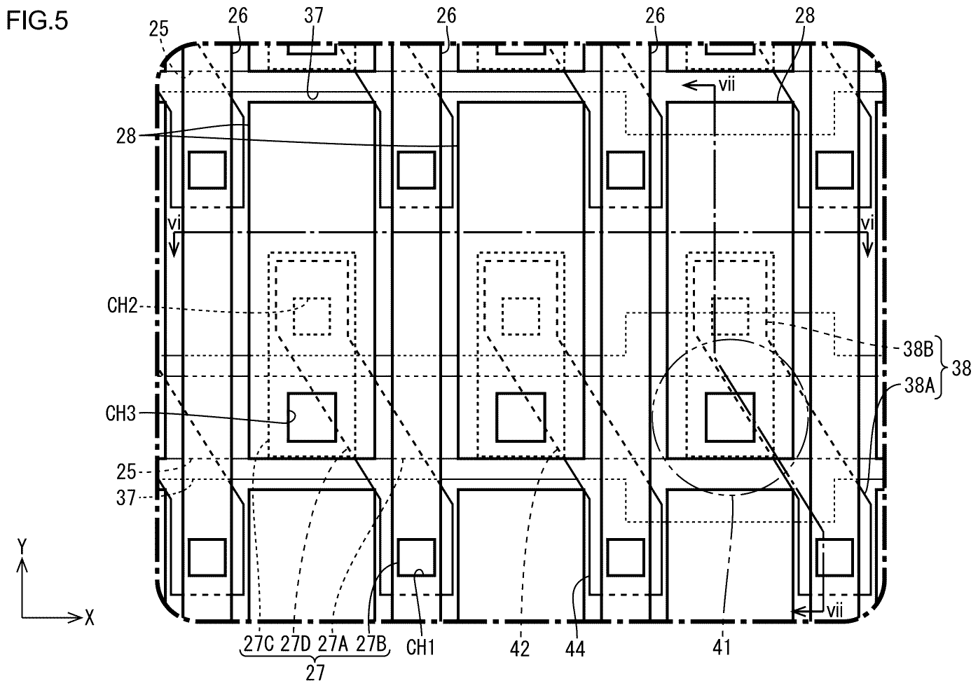

Next, a cross-sectional configuration of the liquid crystal panel 11 will be described with reference to FIG. 4. As illustrated in FIG. 4, the substrates 20, 21 are disposed opposite each other with having a space therebetween with respect to a normal direction to main surfaces of the substrates 20, 21. At least a liquid crystal layer 22 and a sealing portion 23 that seals the liquid crystal layer 22 are disposed between the substrates 20, 21. The liquid crystal layer 22 includes liquid crystal molecules that are substances having optical characteristics that change according to application of an electric field. The sealing portion 23 has a rectangular frame plan view shape (endless loop shape) as a whole and surrounds the entire periphery of the liquid crystal layer 22 in the non-display area NAA. The sealing portion 23 keeps the gap (a cell gap) corresponding to the thickness of the liquid crystal layer 22. Polarizing plates 24 are bonded to outer surfaces of the substrates 20, 21, respectively.

Pixel arrangement in the display area AA of the array substrate 21 will be described with reference to FIG. 5. Gate lines 25 (first lines, scanning lines) and source lines 26 (second lines, image lines) are routed with crossing each other in an area of the inner surface of the array substrate 21 in the display area AA. The gate lines 25 extend along the X-axis direction and cross the display area AA laterally. The gate lines 25 are arranged at intervals in the Y-axis direction. The gate lines 25 are supplied with the scan signals that are output from the first circuit 14A. The source lines 26 extend along the Y-axis direction and cross the display area AA vertically. The source lines 26 and the gate lines 25 cross each other. The source lines 26 are arranged at intervals in the X-axis direction. The image signals output from the second circuit 14B are supplied to the source lines 26. TFTs 27 (switching components) and pixel electrodes 28 are arranged in areas near the crossing portions where the gate lines 25 and the source lines 26 cross. The TFTs 27 and the pixel electrodes 28 are arranged regularly along the X-axis direction and the Y-axis direction. The TFTs 27 include gate electrodes 27A (first electrode), source electrodes 27B (second electrode), drain electrodes 27C (third electrode), and semiconductor sections 27D. The gate electrodes 27A are connected to the gate lines 25, respectively. The source electrodes 27B are connected to the source lines 26, respectively. The drain electrodes 27C are connected to the pixel electrodes 28, respectively. The semiconductor sections 27D are made of semiconductor material and include first end portions that are connected to the source electrodes 27B, respectively, and second end portions that are connected to the drain electrodes 27C, respectively. The semiconductor sections 27D include middle sections that are between the first end portion and the second end portion and overlap the gate electrodes 27A, respectively. The TFTs 27 turn on based on the scanning signals supplied to the gate electrodes 27A via the gate lines 25. Then, the pixel electrodes 28 are charged at potentials related to the image signals supplied to the source electrodes 27B via the source lines 26. The pixel electrodes 28 have a long shape elongated in the Y-axis direction.

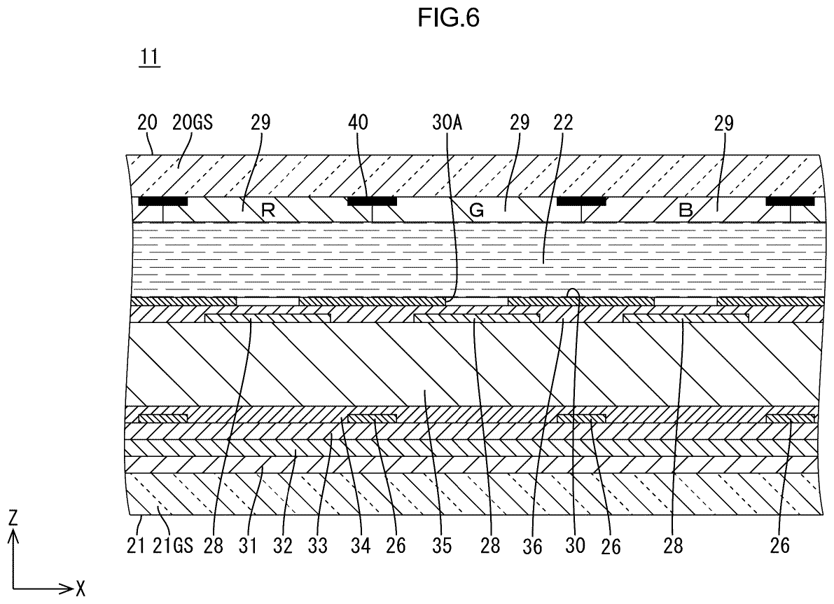

As illustrated in FIG. 6, a common electrode 30 is disposed in the display area AA on an inner surface side of the array substrate 21. The common electrode 30 is included in an upper layer than the pixel electrodes 28 and spreads over substantially an entire area of the display area AA. Therefore, the common electrode 30 is disposed to overlap all the pixel electrodes 28 arranged in the display area AA. In the array substrate 21 of this embodiment, with respect to the pixel electrode 28 and the common electrode 30, the common electrode 30 that is included in the upper layer is defined as the upper electrode and the pixel electrode 28 that is included in the lower layer is defined as the lower electrode. The common electrode 30 includes slits 30A in portions overlapping the pixel electrodes 28, respectively. The common electrode 30 is supplied with common potential signals of a common potential (a reference potential). When the pixel electrode 28 is charged at a potential based on the image signal transmitted to the source line 26 according to the driving of the TFT 27, a potential difference occurs between the pixel electrode 28 and the common electrode 30. Then, a fringe electric field (an oblique electric field) is created between an opening edge of the slit 30A in the common electrode 30 and the pixel electrode 28. The fringe electric field includes a component parallel to the plate surface of the array substrate 21 and a component normal to the plate surface of the array substrate 21. With the fringe electric field, orientations of the liquid crystal molecules included in the liquid crystal layer 22 can be controlled and predefined display is performed based on the orientations of the liquid crystal molecules. Namely, the liquid crystal panel 11 according to this embodiment operates in fringe field switching (FFS) mode.

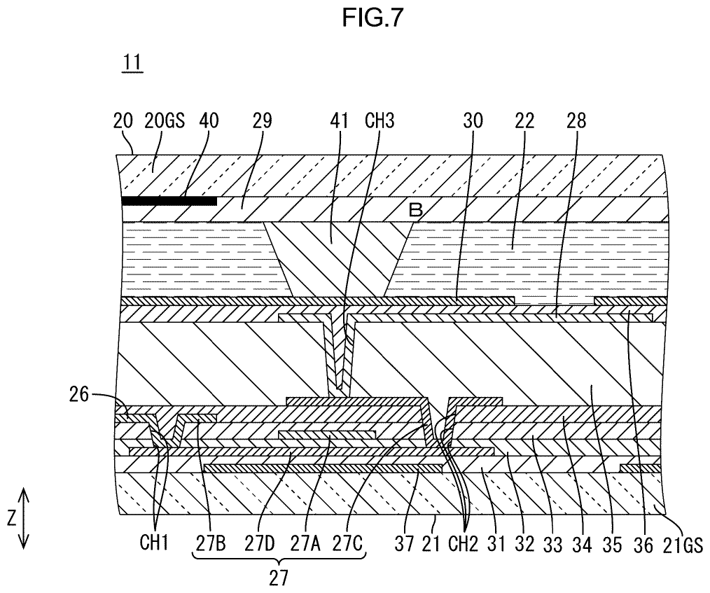

Next, various films that are disposed in layers on the glass substrate 21GS of the array substrate 21 will be described in detail with reference to FIGS. 6 and 7. As illustrated in FIGS. 6 and 7, on the glass substrate 21GS of the array substrate 21, the following films are at least disposed on top of each other in the following order from the lowest layer (the grass substrate GS side): a first metal film, a basecoat film 31, a semiconductor film, a gate insulation film 32 (a first insulation film), a second metal film, a first interlayer insulation: film 33, a third metal film, a second interlayer insulation film 34, a first transparent electrode film, a first planarization film 35, a second transparent electrode film, a third interlayer insulation film 36, a third transparent electrode film, and an alignment film.

Each of the first metal film, the second metal film, and the third metal film is a single-layer film made of one kind of metal, a multilayer film made of different kinds of metals, or alloy, and has electrically conductive properties and light blocking properties. The first metal film is a single-layer film made of tungsten (W), for example, and has a thickness of about 50 nm. As illustrated in FIG. 7, a portion of the first metal film is configured as a first light blocking portion 37. The second metal film is a multilayer film made of a titanium (Ti) layer of about 100 nm thickness, an aluminum (Al) layer of about 150 nm thickness, and a Ti layer of about 30 nm thickness that are disposed on top of each other in this order from the lower layer side. Portions of the second metal film are configured as the gate lines 25 and the gate electrodes 27A. A portion of the gate line 25 that overlaps the semiconductor section 27D in a plan view is configured as the gate electrode 27A. The third metal film is a multilayer film made of a titanium layer (Ti) of about 60 nm thickness, an aluminum (Al) layer of about 300 nm thickness, and a Ti layer of about 20 nm thickness that are disposed on top of each other in this order from the lower layer side. As illustrated in FIG. 6, portions of the third metal film are configured as the source lines 26. A portion of the source line 26 that overlaps the semiconductor section 27D in a plan view is configured as the source electrode 27B.

The first transparent electrode film, the second transparent electrode film, and the third transparent electrode film are made of transparent electrode material. The first transparent electrode film is made of indium zinc oxide (IZO) and has a thickness of about 100 nm. As illustrated in FIG. 7, portions of the first transparent electrode film are configured as the drain electrodes 27C. One ends of the drain electrodes 27C are connected semiconductor sections 27D, respectively. The second transparent electrode film is made of indium tin oxide (ITO) and has a thickness of about 100 nm. Portions of the second transparent electrode film are configured as the pixel electrodes 28. One ends of the pixel electrodes 28 are connected to other ends of the drain electrodes 27C, respectively. The third transparent electrode film is made of IZO, for example, and has a thickness of about 100 nm. A portion of the third transparent electrode film is configured as the common electrode 30.

The semiconductor film is made of oxide semiconductor material. In detail, the semiconductor film is an oxide semiconductor thin film including indium (In), which is one example of oxide semiconductor, gallium (Ga), and zinc (Zn). The oxide semiconductor thin film including indium (In), gallium (Ga), and zinc (Zn) is non-crystalline or crystalline. The semiconductor film has a thickness of about 50 nm. The oxide semiconductor material of the semiconductor film has higher resistance value with no voltage being applied (OFF state) compared to silicon semiconductor material. The oxide semiconductor material of the semiconductor film has higher electron mobility than the amorphous silicon semiconductor material.

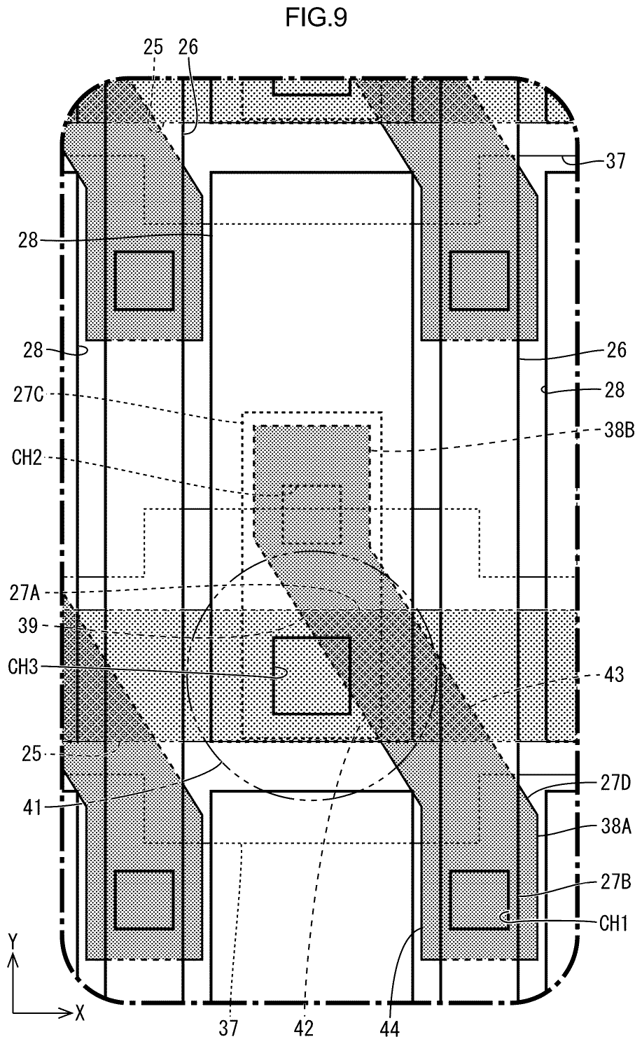

The semiconductor film of this embodiment is subjected to a resistance lowering process in a producing process and resistance is lowered in portions of the semiconductor film. Accordingly, the semiconductor section 27D includes a resistance lowered section 38. A portion of the semiconductor section 27D that is not subjected to the resistance lowering process is defined as a resistance non-lowered section 39. In FIG. 9, the resistance lowered section 38 of the semiconductor section 27D is illustrated with shading. Electrons can move through the resistance non-lowered section 39 of the semiconductor section 27D under a particular condition (when the scanning signals are supplied to the gate electrode 27A). Namely, the resistance non-lowered section 39 functions as a channel section under the particular condition. The resistance non-lowered section 39 overlaps the gate electrode 27A of the semiconductor section 27D in a plan view. The resistance lowered section 38 corresponds to the portion of the semiconductor section 27D that does not overlap the gate electrode 27A in a plan view. The resistivity of the resistance lowered section 38 is quite lower than that of the resistance non-lowered section 39 and is about 1/10,000,000,000 to 1/100 of the resistivity of the resistance non-lowered section 39. Electrons can always move through the resistance lowered section 38 and the resistance lowered section 38 functions as an electrically conductive member. In the process of producing the array substrate 21, after forming the gate lines 25 and the gate electrodes 27A that are portions of the second metal film, the gate lines 25 and the gate electrodes 27A are used as a mask when the semiconductor film is subjected to the resistance lowering process. In the resistance lowering process, the portions of the semiconductor film that are not covered by the gate lines 25 and the gate electrodes 27A (non-overlapping portions, uncovered portions) are subjected to the resistance lowering process and the portions 41 of the semiconductor film that are covered by the gate lines 25 and the gate electrodes 27A (overlapping portions, covered portions) are not subjected to the resistance lowering process. Examples of the resistance lowering process include a plasma surface treatment and an annealing treatment with using gas such as NH₃, H₂, N₂, He. The resistance lowered section 38 includes a first resistance lowered section 38A (a source section) that is connected to the source electrode 27B and a second resistance lowered section 38B (a drain section) that is connected to the drain electrode 27C.

Each of the basecoat film 31, the gate insulation film 32, the first interlayer insulation film 33, the second interlayer insulation film 34, and the third interlayer insulation film 36 is made of inorganic material (inorganic resin material). The basecoat film 31 is a multilayer film including a SiO₂ (silicon dioxide, silicon oxide) layer of about 100 nm thickness and a SiNₓ (silicon nitride) layer of about 70 nm thickness that are disposed on top of each other from a lower layer side. The basecoat film 31 is between the first light blocking portion 37 and each of the gate line 25 and the gate electrode 27A and keeps insulation therebetween. The gate insulation film 32 is a single-layer film made of SiO₂ and has a thickness of about 85 nm. The gate insulation film 32 is between the semiconductor section 27D and each of the gate line 25 and the gate electrode 27A and keeps insulation therebetween. The first interlayer insulation film 33 is a single-layer film made of SiO₂ and has a thickness of about 500 nm. The first interlayer insulation film 33 is between the gate line 25 and the source line 26 and keeps insulation therebetween. The second interlayer insulation film 34 is a single-layer film made of SiO₂ and has a thickness of about 500 nm. The second interlayer insulation film 34 is between the source line 26 and the drain electrode 27C and keeps insulation therebetween. The third interlayer insulation film 36 is a single-layer film made of SiNₓ and has a thickness of about 100 nm. The third interlayer insulation film 36 is between the pixel electrode 28 and the common electrode 30 and keeps insulation therebetween.

The first planarization film 35 is made of organic material (organic resin material) such as PMMA (acrylic resin). The first planarization film 35 that is made of organic material normally has a film thickness greater than that of the basecoat film 31, the gate insulation film 32, the first interlayer insulation film 33, the second interlayer insulation film 34, and the third interlayer insulation film 36 that are made of inorganic material. Specifically, the thickness of the first planarization film 35 is about 2 μm. The first planarization film 35 is between the drain electrode 27C and the pixel electrode 28.

As illustrated in FIGS. 6 and 7, on the glass substrate 20GS of the opposed substrate 20, color filters 29, second light blocking portions 40, spacers 41, and an alignment film are disposed. The alignment film included in each of the opposed substrate 20 and the array substrate 21 is made of organic material such as polyimide. The alignment film is disposed on an innermost surface side (closest to the liquid crystal layer 22) of the opposed substrate 20 and the array substrate 21. The upper surfaces of the alignment films that are opposite the liquid crystal layer 22 are subjected to the photo-orientation treatment and have a function of orienting the liquid crystal molecules.

As illustrated in FIGS. 6 and 7, the color filters 29 are disposed to overlap the pixel electrodes 28 of the array substrate 21 and the color filter 29 and the pixel electrode 28 that are overlapped are configured as a pixel, which is a display unit. The color filters 29 include multiple kinds (three) of color filters that exhibit different colors. The color filters 29 that exhibit different colors are arranged along the extending direction in which the gate lines 25 extend (in the X-axis direction). The color filters 29 that exhibit different colors are arranged in the X-axis direction. The color filters 29 that exhibit different colors extend along the extending direction in which the source lines 26 extend (substantially the Y-axis direction). Namely, the color filters 29 that exhibit different colors are arranged in a stripe pattern as a whole. The color filters 29 that exhibit different colors are arranged such that boundaries therebetween (a color boundary) overlap the source lines 26. The color filters 29 include a green color filter (first color filter) that exhibits green, a blue color filter (second color filter) that exhibits blue, and a red color filter (third color filter) that exhibits red. The green color filter and the pixel electrode 28 that overlaps the green color filter are configured as a green pixel (first pixel) that exhibits green. The blue color filter and the pixel electrode 28 that overlaps the blue color filter are configured as a blue pixel (second pixel) that exhibits blue. The red color filter and the pixel electrode 28 that overlaps the red color filter are configured as a red pixel (third pixel) that exhibits red. In FIG. 6, the colors exhibited by the color filters 29 are represented by R (red), G (green), and B (blue).

The second light blocking portions 40 are made of synthetic resin having good light blocking properties. As illustrated in FIG. 6, the second light blocking portions 40 are disposed on an inner surface of the glass substrate 20GS. The second light blocking portions 40 extend along the Y-axis direction and overlap the source lines 26 of the array substrate 21. The second light blocking portions 40 are arranged at intervals in the X-axis direction and are arranged in a stripe pattern in a plan view. The second light blocking portions 40 are disposed on border sections that define each of the color filters 29 that exhibit different colors. The interval between the second light blocking portions 40 is substantially same as the interval between the source lines 26. This prevents colors from mixing and each color of the pixels can be surely displayed clearly.

As illustrated in FIG. 7, the spacers 41 project from the opposed substrate 20 toward the array substrate 21 along the Z-axis direction (the normal direction to the surface of the opposed substrate 20). In detail, the spacers 41 are made of resin and project from the surfaces of the color filters 29 in the display are AA of the opposed substrate 20 toward the array substrate 21 along the Z-axis direction. The projecting end surfaces of the spacers 41 are opposite the array substrate 21. The spacers 41 have a tapered columnar shape as a whole. The spacers 41 may include two kinds of spacers that have different projection dimensions measured from the color filters 29. The spacer 41 illustrated in FIG. 7 has a greater projection dimension. The projecting end surfaces of the spacers 41 having a greater projection dimension are contacted with the inner surface of the array substrate 21 (the alignment film). On the other hand, the projecting end surfaces of the spacers 41 having a smaller projection dimension are spaced away from the inner surface of the array substrate 21 with a clearance. Only when one of the substrates 20, 21 is deformed inwardly due to any external force, the projecting end surface of the spacer 41 having a smaller projection dimension comes in contact with the inner surface of the array substrate 21. Such spacers 41 maintain the distance between the substrates 20, 21 (the thickness of the liquid crystal layer 22, a cell gap). As illustrated in FIG. 5, the spacer 41 overlaps the gate electrode 27A of a specific one of the TFTs 27 that are arranged in the X-axis direction (for example, the TFT 27 that is connected to the pixel electrode 28 of a blue pixel, which has lowest luminous efficiency function).

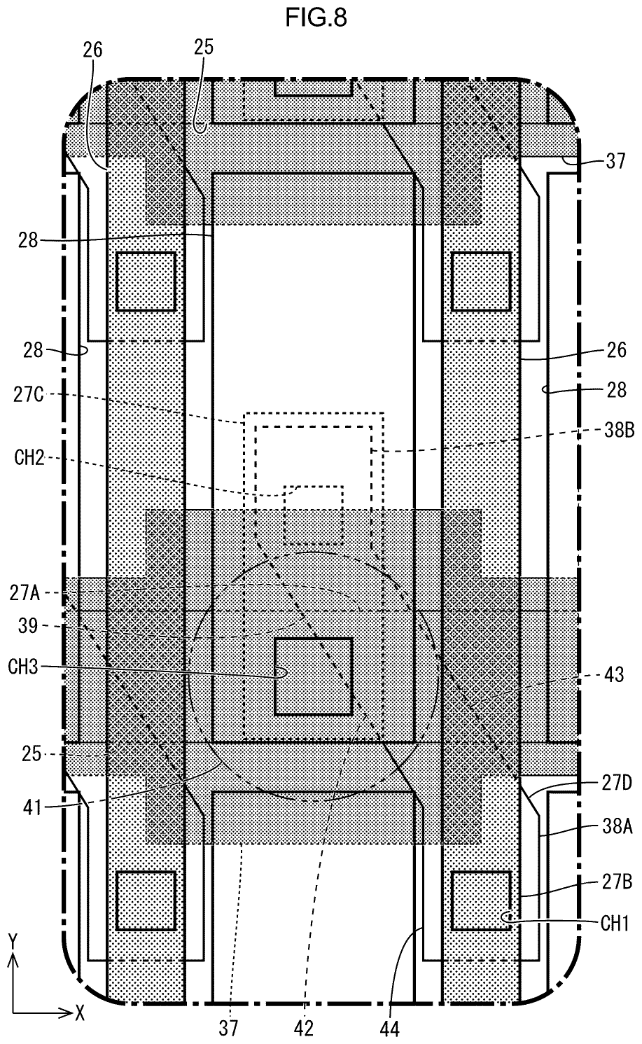

Next, the planar shape of the first light blocking portion 37, which is a portion of the first metal film, will be described with reference to FIG. 8. In FIG. 8, the configurations of the portions of the first metal film and the third metal film (the first light blocking portions 37 and the source lines 26) are illustrated with different types of shadings. As illustrated in FIG. 8, the first light blocking portion 37 has a laterally elongated belt shape extending in the X-axis direction and overlaps an entire area of the gate line 25 in a plan view. The width dimension of the first light blocking portion 37 is greater than the width dimension of the gate line 25 and two edges of the first light blocking portion 37 with respect to the width direction (the Y-axis direction) are outside the two edges of the gate line 25. Therefore, the first light blocking portion 37 covers an entire area of the resistance non-lowered section 39 (the channel section) of the semiconductor section 27D from the back side. The resistance non-lowered section 39 overlaps the gate electrode 27A, which is a portion of the gate line 25. Accordingly, light rays that travel from the backlight 12 toward the resistance non-lowered section 39 can be efficiently blocked by the first light blocking portion 37. If light is supplied to the resistance non-lowered section 39, the characteristics of the TFT 27 may be changed; however, with the first light blocking portion 37, such change in characteristic is less likely to be caused. The first light blocking portion 37 includes a wide section that overlaps the spacer 41 and the wide section is wider than other sections of the first light blocking portion 37.

Next, a plan-view configuration of the drain electrodes 27C, which are portions of the first transparent electrode film, and the pixel electrodes 28, which are portions of the second transparent electrode film, will be described. As illustrated in FIG. 8, the drain electrode 27C and the pixel electrode 28 have a vertically elongated rectangular shape extending in the Y-axis direction. The long-side dimension (the dimension measured in the Y-axis direction) of the pixel electrode 28 is greater than the long-side dimension of the drain electrode 27C. The pixel electrode 28 is disposed between two gate lines 25 with respect to the Y-axis direction. The pixel electrode 28 is disposed such that a first end portion overlaps one of the two gate lines 25 (a lower one in FIG. 8) and a second end portion is spaced away from other one of the two gate lines 25 (an upper one in FIG. 8) with respect to the Y-axis direction. An entire area of the drain electrode 27C overlaps the pixel electrode 28. The drain electrode 27C is disposed closer to the first end portion (a lower end portion in FIG. 8) of the pixel electrode 28. The drain electrode 27C is disposed such that a first end portion (a lower end portion in FIG. 8) overlaps the first end portion of the pixel electrode 28 and the gate line 25 (the gate electrode 27A) and a second end portion (an upper end portion in FIG. 8 overlaps a second end portion of the semiconductor section 27D (the second resistance lowered section 38B). The first end portions of the pixel electrode 28 and the drain electrode 27C overlap the gate line 25 (the gate electrode 27A) and also overlap the first light blocking portion 37 and the resistance non-lowered section 39 of the semiconductor section 27D.

A plan-view configuration of the semiconductor section 27D, which is a portion of the semiconductor film, will be described with reference to FIG. 9. In FIG. 9, the configurations that are portions of the second metal film and the semiconductor film (the gate lines 25, and the gate electrodes 27A and the semiconductor section 27D) are illustrated with different types of shadings. As illustrated in FIG. 9, the semiconductor section 27D includes a first extending portion 42 that extends in a direction that is oblique with respect to both of the extending direction in which the gate lines 25 extend (the X-axis direction) and the extending direction in which the source lines 26 extend (the Y-axis direction). The first extending portion 42 crosses the gate line 25. The first extending portion 42 includes a first end portion (a lower end portion in FIG. 9) and a second end portion (an upper end portion in FIG. 9). The first end portion of the first extending portion 42 is on an opposite side from a target pixel electrode 28, to which the semiconductor section 27D is to be connected, with the first end portion and the second end portion sandwiching the gate line 25 with respect to the Y-axis direction. The first end portion of the first extending portion 42 overlaps the source line 26. The second end portion of the first extending portion 42 is on the target pixel electrode 28 side (on the upper side in FIG. 9) with the first end portion and the second end portion sandwiching the gate line 25 with respect to the Y-axis direction. The second end portion of the first extending portion 42 overlaps the drain electrode 27C. The first extending portion 42 extends farther away from the source line 26 and closer to the drain electrode 27C as it extends from the first end portion to the second end portion. The first extending portion 42 extends to cross the gate line 25. The first extending portion 42 extends outside from two edges of the gate line 25 with respect to the Y-axis direction. The first extending portion 42 includes an entire area of the resistance non-lowered section 39, a portion of the first resistance lowered section 38A, and a portion of the second resistance lowered section 38B. In detail, the first extending portion 42 includes a first portion that is disposed on the source electrode 27B side (on the lower side in FIG. 9) with respect to the gate line 25 in the Y-axis direction and the first portion corresponds to a portion of the first resistance lowered section 38A (that is closer to the resistance non-lowered section 39 than the connection portion connected to the source electrode 27B is). The first extending portion 42 includes a second portion that is disposed on the drain electrode 27C side (on the upper side in FIG. 9) with respect to the gate line 25 in the Y-axis direction and the second portion corresponds to a portion of the second resistance lowered section 38B (that is closer to the resistance non-lowered section 39 than the connection portion connected to the drain electrode 27C is).

As illustrated in FIG. 9, the semiconductor section 27D includes the resistance non-lowered section 39 that overlaps the gate electrode 27A, the first resistance lowered section 38A that is closer to the source electrode 27B (on the lower side in FIG. 9) than the resistance non-lowered section 39 is, and the second resistance lowered section 38B that is closer to the drain electrode 27C (on the upper side in FIG. 9) than the resistance non-lowered section 39 is. As illustrated in FIG. 7, a first end portion of the semiconductor section 27D, which is the first resistance lowered section 38A, overlaps the source line 26 and is connected to the source electrode 27B, which is a portion of the source line 26. The gate insulation film 32 and the first interlayer insulation film 33, which are disposed between the first end portion of the semiconductor section 27D and the source electrode 27B, include first contact holes CH1 at a position overlapping the first end portion of the semiconductor section 27D and the source electrode 27B. The first contact holes CH1, which extend through the gate insulation film 32 and the first interlayer insulation film 33, are communicated with each other. The first end portion of the semiconductor section 27D and the source electrode 27B are connected through the first contact holes CH1.

As illustrated in FIG. 7, a second end portion of the semiconductor section 27D, which is the second resistance lowered section 38B, overlaps the drain electrode 27C and is connected to the drain electrode 27C. The gate insulation film 32, the first interlayer insulation film 33, and the second interlayer insulation film 34, which are disposed between the second end portion of the semiconductor section 27D and a second end portion (overlapping end portion) of the drain electrode 27C, include second contact holes CH2 at a position overlapping the second end portion of the semiconductor section 27D and the second end portion of the drain electrode 27C. The second contact holes CH2, which extend through the gate insulation film 32, the first interlayer insulation film 33, and the second interlayer insulation film 34, are communicated with each other. The second end portion of the semiconductor section 27D and the second end portion of the drain electrode 27C are connected through the first contact holes CH2. The drain electrode 27C includes a first end portion that is opposite from the second end portion. The first planarization film 35, which is disposed between the first end portion of the drain electrode 27C and the first end portion of the pixel electrode 28, includes a third contact hole CH3 at a position overlapping the first end portion of the drain electrode 27C and the first end portion of the pixel electrode 28. The first end portion of the drain electrode 27C and the first end portion of the pixel electrode 28 are connected through the third contact hole CH3. The third contact hole CH3 overlaps the gate electrode 27A, the first light blocking portion 37, and the spacer 41.

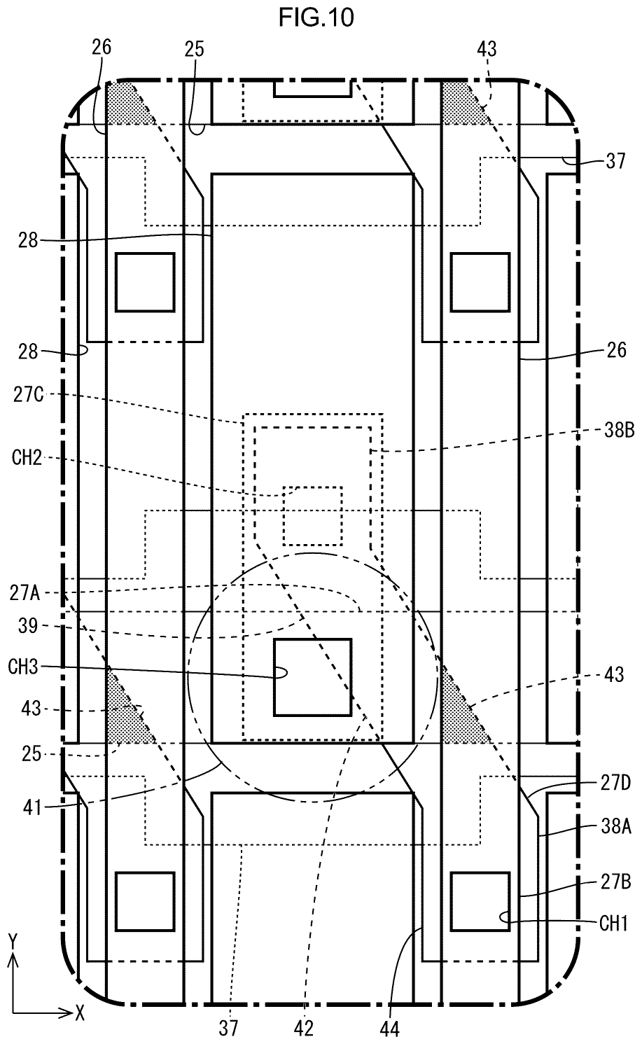

As illustrated in FIGS. 9 and 10, the semiconductor section 27D includes a first overlapping portion 43 that overlaps the gate electrode 27A and the source line 26. The first overlapping portion 43 is illustrated with shading in FIG. 10. The first overlapping portion 43 that overlaps the gate electrode 27A corresponds to a portion of the resistance non-lowered section 39 and also corresponds to a portion of the first extending portion 42. Namely, the first extending portion 42 of the semiconductor section 27D is disposed such that a portion of the resistance non-lowered section 39 overlapping the gate electrode 27A overlaps a portion of the source line 26. In detail, a portion (a lower portion in FIGS. 9 and 10) of the resistance non-lowered section 39 that is close to the first resistance lowered section 38 is configured as the first overlapping portion 43. The first overlapping portion 43 is a triangular plan view area (more specifically, a right-angled triangular area). The triangular area is defined by three sides that match, respectively, one side edge of the source line 26 (on the drain electrode 27C side with respect to the X-axis direction), one side edge of the first extending portion 42 (on the opposite side from the drain electrode 27C side with respect to the X-axis direction), and one side edge of the gate line 25 (on the source electrode 27B side with respect to the Y-axis direction).

As illustrated in FIGS. 9 and 10, the semiconductor section 27D includes the first overlapping portion 43 that overlaps the gate electrode 27A and the source line 26. Therefore, compared to the configuration in which the semiconductor section does not overlap the source line, parasitic capacitance created between the first resistance lowered section 38A, which is a portion of the resistance lowered section 38 charged at a same potential as the source line 26, and other electrode and lines can be reduced. Particularly in this embodiment, the first extending portion 42 including the first overlapping portion 43 extends obliquely with respect to the gate lines 25 and the source lines 26. Therefore, the area of overlapping portions of the semiconductor section 27D and the source line 26 is smaller than the area of overlapping portions of the first extending portion extending parallel to the source line 26 and the source line 26. Therefore, parasitic capacitance created between the first resistance lowered section 38A, which corresponds to a portion of the resistance lowered section 38 ranging from the second end portion (connected to the drain electrode 27C) to the gate line 25, and the source line 26 can be reduced. Since the second resistance lowered section 38B is charged at a same potential as the drain electrode 27C, parasitic capacitance created between the drain electrode 27C and the source line 26 can be reduced. Therefore, in this embodiment, the parasitic capacitance created between the first resistance lowered section 38A and each of the gate line 25, the first light blocking portion 37, and the pixel electrode 28 can be reduced. Accordingly, a load on the source line 26 can be effectively reduced.

As illustrated in FIGS. 9 and 10, the semiconductor section 27D includes a second extending portion 44 that extends parallel to the source line 26 (the Y-axis direction). The second extending portion 44 includes the first end portion of the semiconductor section 27D that is connected to the source electrode 27B. The second extending portion 44 is a portion of the first resistance lowered section 38A. The first resistance lowered section 38A includes an entire area of the second extending portion 44 and a portion of the first extending portion 42. The second extending portion 44 overlaps the source line 26. The second extending portion 44 includes a first end portion that is connected to the source electrode 27B and a second end portion that is opposite from the first end portion. The second end portion of the second extending portion 44 is continuous to the end portion of the first extending portion 42. Accordingly, compared to a configuration in which the semiconductor section does not include the second extending portion 44 and the first extending portion includes a first end portion of the semiconductor section, the area of overlapping portions of the first resistance lowered section 38A, which is a portion of the resistance lowered section 38 ranging from the first end portion connected to the source electrode 27B to the gate line 25, and the source line 26 is increased. Since the first resistance lowered section 38A is charged at a same potential as the source line 26, parasitic capacitance created between the first resistance lowered section 38A, which is charged at the same potential as the source line 26, and other electrodes or lines can be reduced. Accordingly, a load on the source line 26 can be reduced.

As illustrated in FIGS. 9 and 10, the second end portion of the semiconductor section 27D that is connected to the drain electrode 27C extends parallel to the Y-axis direction. The second resistance lowered section 38B, which is a portion of the resistance lowered section 38 ranging from the second end portion connected to the drain electrode 27C to the gate line 25, does not overlap the source line 26. The second resistance lowered section 38B, which is a portion of the resistance lowered section 38 ranging from the second end portion to the gate line 25, is charged at a same potential as the drain electrode 27C and the second resistance lowered section 38B does not overlap the source line 26. Therefore, parasitic capacitance created between the drain electrode 27C and the source line 26 can be reduced. Accordingly, a load on the source line 26 can be further reduced.

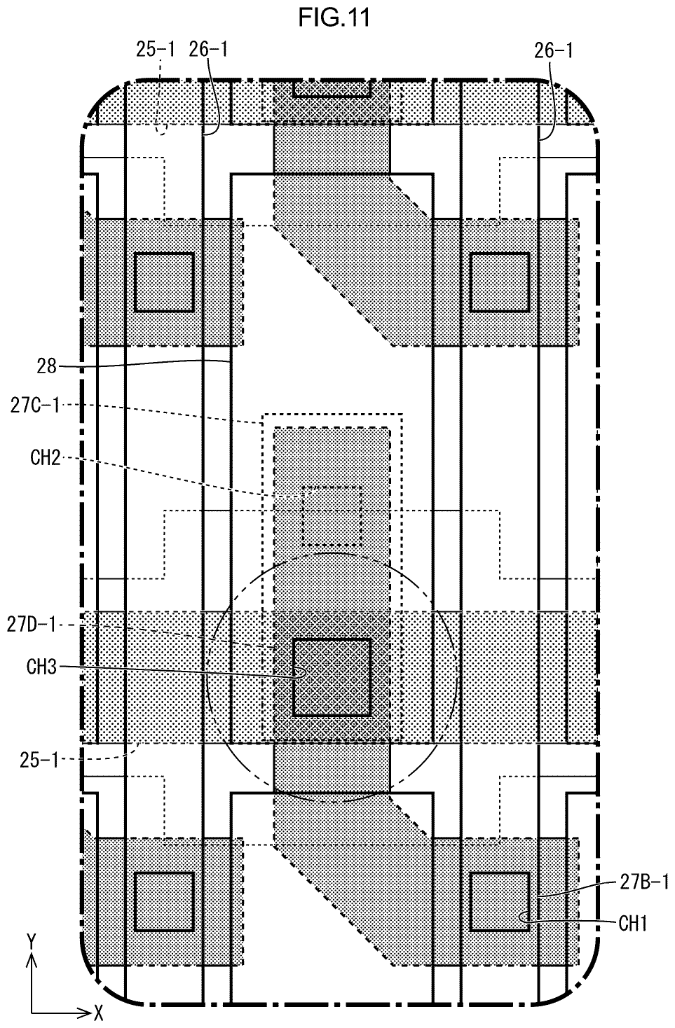

To testify the advantageous effects of the array substrate 21 of this embodiment, Comparative Experiment 1 was performed. In Comparative Experiment 1, parasitic capacitance (electrostatic capacitance) related to the source line 26 was calculated with using Example 1 and Comparative Example 1. The array substrate 21 of Example 1 has the configuration as previously described. The array substrate of Comparative Example 1 does not include the first overlapping portion 43, which is illustrated in FIGS. 9 and 10. Specifically, as illustrated in FIG. 11, in the array substrate of Comparative Example 1, a portion of a semiconductor section 27D-1 that crosses a gate line 25-1 extends parallel to a source line 26-1 and does not overlap the source line 26-1. In detail, the semiconductor section 27D-1 of Comparative Example 1 includes a second end portion that is connected to a drain electrode 27C-1 and extends straight along the Y-axis direction from the second end portion toward the gate line 25-1. The semiconductor section 27D-1 crosses the gate line 25-1 and is curved and extend obliquely with respect to the X-axis direction and the Y-axis direction. A first end portion of the semiconductor section 27D-1 that is an opposite end portion from the second end portion is connected to a source electrode 27B-1, which is a portion of the source line 26-1. Comparative Example 1 has a substantially similar configuration as Example 1 except for the configuration of the semiconductor section 27D-1. The resolution (pixel density) of the array substrates of Example 1 and Comparative Example 1 are 1728 ppi and the interval between the pixels is 14.7 μm.

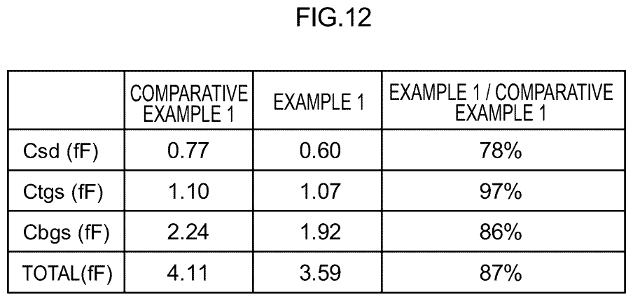

In Comparative Experiment 1, with respect to Example 1 and Comparative Example 1, the parasitic capacitance Csd created between the source line and the pixel electrode, the parasitic capacitance Ctgs created between the source line and the gate line, and the parasitic capacitance Cbgs created between the source line and the first light blocking portion were calculated. The calculation results of the parasitic capacitances Csd, Ctgs, Cbgs are illustrated in FIG. 12. A unit of the parasitic capacitances Csd, Ctgs, Cbgs is fF. In addition to the calculation results of the parasitic capacitances Csd, Ctgs, Cbgs, ratios obtained by dividing the parasitic capacitances Csd, Ctgs, Cbgs of Example 1 by the parasitic capacitances Csd, Ctgs, Cbgs of Comparative Example 1, respectively, are illustrated with percentages in FIG. 12.

Experiment results of Comparative Experiment 1 will be described. With reference to FIG. 12, the parasitic capacitances Csd, Ctgs, Cbgs of Example 1 are lower than those of Comparative Example 1. Particularly, in Example 1, the parasitic capacitance Csd created between the source line 26 and the pixel electrode 28 is largely reduced and is 78% of that of Comparative Example 1. In Example 1, as illustrated in FIG. 9, an entire area of the second resistance lowered section 38B of the resistance lowered section 38 of the semiconductor section 27D does not overlap the source line 26. It is presumed that such a configuration contributes to the large reduction of the parasitic capacitance Csd.

As previously described, the array substrate 21 includes the gate line 25 (a first line), the source line 26 (a second line) that crosses the gate line 25, the semiconductor section 27D that is made of semiconductor material and extends to cross the gate line 25 and includes a first end portion overlapping the source line 26, the gate insulation film 32 (a first insulation film) that is disposed between the gate line 25 and the semiconductor section 27D, the gate electrode 27A (a first electrode) that is a portion of the gate line 25 and overlaps the semiconductor section 27D via the gate insulation film 32, the source electrode 27B (a second electrode) that is a portion of the source line 26 and overlaps the semiconductor section 27D and is connected to the semiconductor section 27D, and the drain electrode 27C (a third electrode) that overlaps a second end portion of the semiconductor section 27D and is connected to the semiconductor section 27D. A portion of the semiconductor section 27D that does not overlap the gate electrode 27A is configured as the resistance lowered section 38 in which the resistance is reduced. The semiconductor section 27D includes the first overlapping portion 43 that overlaps the gate electrode 27A and the source line 26.

With the potential determined by the signal transferred via the gate line 25 being applied to the semiconductor section 27D via the gate electrode 27A, which is a portion of the gate line 25, the portion of the semiconductor section 27D that overlaps the gate electrode 27A via the gate insulation film 32 becomes a channel section. Then, the signal transferred via the source line 26 is supplied to the drain electrode 27C from the source electrode 27B, which is a portion of the source line 26, via the resistance lowered section 38 and the channel section of the semiconductor section 27D. The semiconductor section 27D extends to cross the gate line 25 and the first end portion and the second end portion of the semiconductor section 27D are connected to the source electrode 27B and the drain electrode 27C, respectively. Therefore, the parasitic capacitance that is created between the portion of the resistance lowered section 38 charged at the same potential as the source line 26 and other electrodes or lines may be increased.

The source line 26 crosses the gate line 25 and a portion of the source line 26 overlaps the gate line 25. On the other hand, the gate electrode 27A is a portion of the gate line 25 that overlaps the semiconductor section 27D via the gate insulation film 32. The semiconductor section 27D includes the first overlapping portion 43 that overlaps a portion of the gate electrode 27A and a portion of the source line 26. Therefore, compared to the configuration in which the semiconductor section does not overlap the source line, the parasitic capacitance that is created between the portion of the resistance lowered section 38 charged at the same potential as the source line 26 and other electrodes or lines can be reduced. This can reduce a load on the source line 26.

The semiconductor section 27D includes the first extending portion 42 that extends obliquely with respect to the gate line 25 and the source line 26 and crosses the gate line 25. The first overlapping portion 43 is a portion of the first extending portion 42. The first extending portion 42 that includes the first overlapping portion 43 extends obliquely with respect to the gate line 25 and the source line 26. Therefore, compared to the configuration in which the first extending portion extends parallel to the source line 26 and overlaps the source line 26, the area of overlapping portions of the semiconductor section 27D and the source line 26 is reduced. Therefore, the parasitic capacitance that is created between the portion of the resistance lowered section 38 ranging from the second end portion to the gate line 25 and the source line 26 can be reduced. Since the portion of the resistance lowered section 38 ranging from the second end portion to the gate line 25 is charged at a same potential as the drain electrode 27C, parasitic capacitance created between the drain electrode 27C and the source line 26 can be reduced. This can reduce a load on the source line 26.

The semiconductor section 27D includes the second extending portion 44 that includes the first end portion of the semiconductor section 27D and extends parallel to the source line 26. The second extending portion 44 is continuous to the first extending portion 42 and overlaps the source line 26. According to such a configuration, compared to a configuration in which the semiconductor section does not include the second extending portion 44 and the first extending portion includes an end portion of the semiconductor section, the area of overlapping portions including a portion of the resistance lowered section 38, which ranges from the first end portion to the gate line 25, and the source line 26 is large. Since the portion of the resistance lowered section 38 ranging from the first end portion to the gate line 25 is charged at a same potential as the source line 26, parasitic capacitance created between the portion of the resistance lowered section 38, which is charged at the same potential as the source line 26, and other electrodes or lines can be reduced. Accordingly, a load on the source line 26 can be reduced.

The semiconductor section 27D is disposed such that the portion of the resistance lowered section 38 ranging from the second end portion of the semiconductor section 27D to the gate line 25 does not overlap the source line 26. The portion of the resistance lowered section 38 ranging from the second end portion of the semiconductor section 27D to the gate line 25 is charged at a same potential as the drain electrode 27C and does not overlap the source line 26. Therefore, parasitic capacitance created between the drain electrode 27C and the source line 26 can be further reduced. Accordingly, a load on the source line 26 can be further reduced.

The liquid crystal display device 10 (a display device) according to this embodiment includes the array substrate 21 described above and the opposed substrate 20 that is disposed opposite the array substrate 21. According to such a liquid crystal display device 10, a load on the source line 26 is reduced and therefore, delay response to the signal transferred via the source line 26 is less likely to occur. This improves display quality.

### Second Embodiment

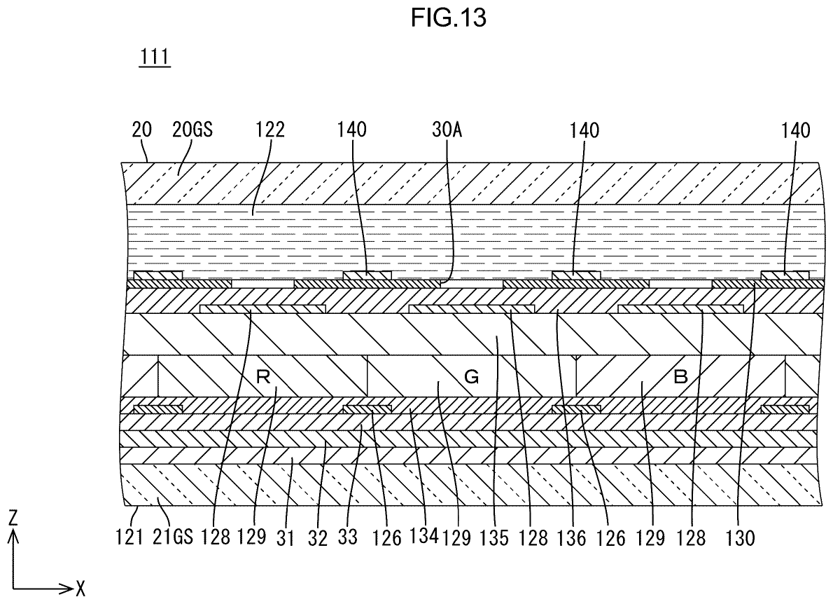

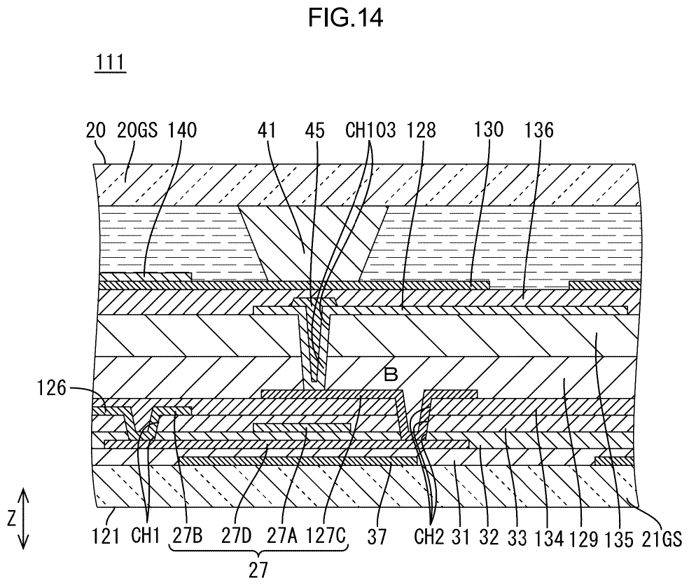

A second embodiment will be described with reference to FIGS. 13 and 14. The second embodiment includes color filters 129 and second light blocking portions 140 that are different from those of the first embodiment. The configurations, operations, and effects of the second embodiment that are similar to those of the first embodiment will not be described.

As illustrated in FIG. 13, an array substrate 121 of this embodiment includes the color filters 129. A liquid crystal panel 111 of this embodiment has a color filter on array (COA) structure. The color filters 129 are disposed in a lower layer than a first planarization film 135. Source lines 126 are included in a lower layer than the color filters 129 via a second interlayer insulation film 134 and overlap border sections (color borders) of the color filters 129 that exhibit different colors. As illustrated in FIG. 14, the color filters 129 are included in an upper layer than drain electrodes 127C that are portions of the first transparent electrode film. Therefore, the color filter 129 and the first planarization film 135 are disposed between a first end portion of the drain electrode 127C and a first end portion of a pixel electrode 128. Accordingly, third contact holes CH103 are through the first planarization film 135 and the color filter 129. In producing the panel, after the first transparent electrode film is subjected to patterning to form the drain electrodes 127C, the color filters 129 and the first planarization film 135 are formed. Then, the third contact holes CH103 are formed through the color filters 129 and the first planarization film 135. The color filters 129 are made of photosensitive resin material and has a thickness of about 1 μm, for example. The first planarization film 135 has a thickness of about 1 μm, for example. Namely, the color filters 129 and the first planarization film 135 have about a same thickness and a total of the thicknesses of the color filter 129 and the first planarization film 135 is about equal to the thickness (about 2 μm) of the first planarization film 35 of the first embodiment.

As illustrated in FIG. 14, the array substrate 121 includes insulation portions 45 in the third contact holes CH103. The insulation portions 45 are portions of a second planarization film that is included in an upper layer than the pixel electrodes 128 that are portions of the second transparent electrode film and in a lower layer than a third interlayer insulation film 136. The third contact hole CH193 is filled with the insulation portion 45. Therefore, the insulation portion 45 that is in the third contact hole CH103 covers the drain electrode 127C and the pixel electrode 128. The pixel electrodes 128, the third interlayer insulation film 136, the common electrode 130, and the alignment film that are included in upper layers than the second planarization film are planarized with the insulation portions 45. Upper portions of the insulation portions 45 are higher than opening edges of the third contact holes CH103 in the first planarization film 135.

As illustrated in FIG. 13, the array substrate 121 of this embodiment includes the second light blocking portions 140 in addition to the color filters 129 and the insulation portions 45. The second light blocking portions 140 are included in an upper layer than the common electrode 130, which is a portion of the third transparent electrode film, and are directly in contact with the common electrode 130. The second light blocking portions 140 are portions of a light blocking film having the following configuration. The light blocking film, portions of which are configured as the second light blocking portion 140, has a multilayer structure including a light blocking layer made of metal material (for example, molybdenum (Mo)), a first transmissive layer made of light transmissive resin material (for example, SiNₓ), a reflective transmissive layer made of metal material (for example, Mo), and a second transmissive layer made of light transmissive resin material (for example, SiNₓ) from a lower layer side. The light blocking layer has a function of blocking light from the backlight 12. The thickness of the light blocking layer is preferably about 30 nm or greater to exert the light blocking function. The first transmissive layer has a function of reducing reflection of external light with using the thin-film interference. The thickness of the first transmissive layer is preferably from 20 nm to 100 nm to exert the function of reducing external light reflection. The reflective transmissive layer has a function of reducing reflection of external light and a function of reflecting again the reflected light reflected by the light blocking layer. The thickness of the reflective transmissive layer is preferably from 3 nm to 20 nm to exert the above-described functions. The second transmissive layer has a function of reducing reflection of external light with using the thin-film interference. The thickness of the second transmissive layer is smaller than the thickness of the first transmissive layer. Portions of the light blocking film having such a configuration are configured as the second light blocking portions 140. The light blocking film may be a single layer structure or a multilayer structure made of metal material having light blocking properties or may be a single layer structure or a multilayer structure made of light blocking resin material. In this embodiment, the second light blocking portions 140 are included in an upper layer than the common electrode 130 and is a second closest layer to the liquid crystal layer 122 subsequent to the alignment film. Therefore, the second light blocking portions 140 can block a large amount of light rays that may cause mixing of the colors between the pixels exhibiting different colors. Accordingly, the mixing of colors is not caused. With the configuration of this embodiment, the operations and effects similar to those of the first embodiment can be obtained.

### Third Embodiment

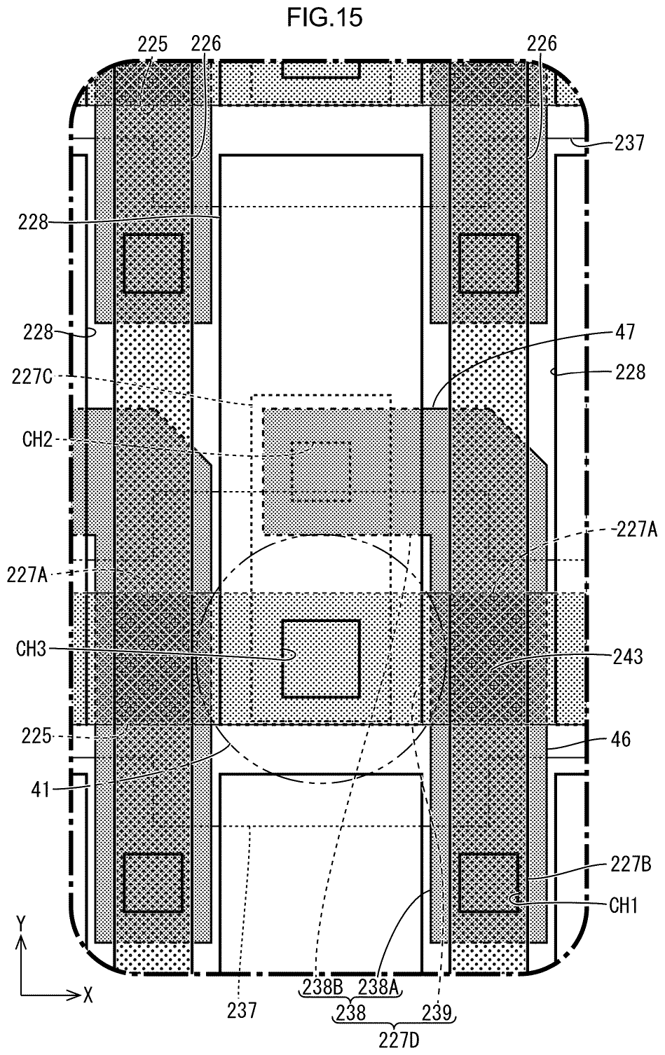

A third embodiment will be described with reference to FIGS. 15 to 17. The third embodiment includes semiconductor sections 227D that have a configuration different from that of the semiconductor sections 27D of the first embodiment. The configurations, operations, and effects of the third embodiment that are similar to those of the first embodiment will not be described.

As illustrated in FIG. 15, the semiconductor section 227D of this embodiment includes a third extending portion 46 that extends along a source line 226 (the Y-axis direction). In FIG. 15, the configuration of the second metal film (gate lines 225) and the configuration of the semiconductor film (gate electrodes 227A, the semiconductor sections 227D) are illustrated with different kinds of shadings. The third extending portion 46 includes a first end portion of the semiconductor section 227D that is connected to the source electrode 227B and extends to cross the gate line 225. The third extending portion 46, which crosses the gate line 225, extends outside from two edges of the gate line 225 with respect to the Y-axis direction. The third extending portion 46 includes an entire area of a resistance non-lowered section 239, an entire area of a first resistance lowered section 238A, and a portion of a second resistance lowered section 238B. The third extending portion 46 overlaps the source line 226. The width of the third extending portion 46 is greater than that of the source line 226. The two edges of the third extending portion 46 with respect to the width direction (the X-axis direction) are outside the two edges of the source line 226 with respect to the X-axis direction. The gate electrode 227A, which is a portion of the gate line 225 overlapping the semiconductor section 227D, overlaps the third extending portion 46 and the source line 226. The semiconductor section 227D includes a fourth extending portion 47 that extends along the gate line 225 (the X-axis direction). The fourth extending portion 47 includes a second end portion of the semiconductor section 227D that is connected to the drain electrode 227C. An end portion of the fourth extending portion 47 that is opposite from the second end portion is continuous to an end portion of the third extending portion 46 that is opposite from the first end portion. An entire area of the fourth extending portion 47 and a portion of the third extending portion 46 are configured as the second resistance lowered section 238B.

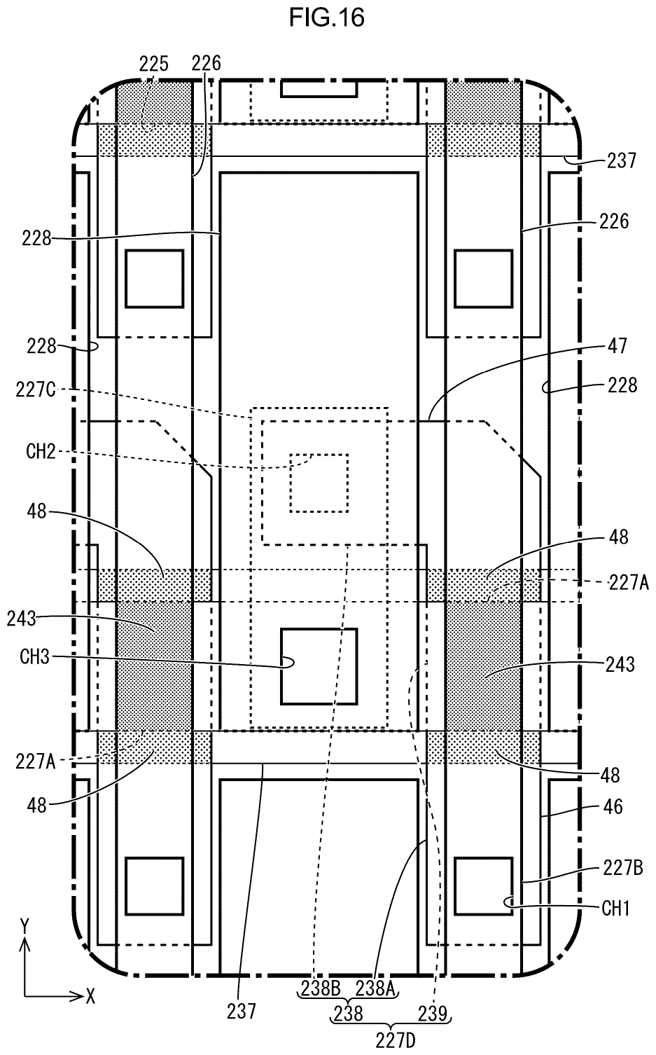

In this embodiment, the third extending portion 46 extends in the Y-axis direction and crosses the gate line 225 and is disposed to overlap the source line 226. Therefore, as illustrated in FIG. 16, a first overlapping portion 243 is a portion of the third extending portion 46. In FIG. 16, the first overlapping portion 243 and a second overlapping portion 48, which will be described later, are illustrated with different kinds of shadings. The first overlapping portion 243 has a vertically long rectangular plan view shape. The first overlapping portion 243 has a width that is equal to the width of the source line 226 and a length that is equal to the width of the gate line 225. The plan view area of the first overlapping portion 243 substantially matches the plan view area of the gate electrode 227A. The area of the first overlapping portion 243 of this embodiment is greater than that of the first overlapping portion 43 of the first embodiment (refer to FIG. 10). The third extending portion 46, which includes the first overlapping portion 243, extends along the source line 226 and is disposed to overlap the source line 226. With such a configuration, compared to the first extending portion 42 of the first embodiment (refer to FIG. 10), the area of overlapping portions of the resistance non-lowered section 239 or the semiconductor section 227D and the gate line 225 (the gate electrode 227A) is smaller. Therefore, parasitic capacity that is created between the first resistance lowered section 238A, which is a portion ranging from the first end portion of the resistance lowered section 238 to the gate line 225, and the gate line 225 can be reduced. Since the first resistance lowered section 238A is charged at a same potential as the source electrode 227B, the parasitic capacity created between the gate line 225 and the source line 226 can be reduced and a load on the source line 226 can be further reduced.

As illustrated in FIG. 16, a first light blocking portion 237 that is wider than the gate line 225 includes the second overlapping portion 48. The second overlapping portion 48 does not overlap the gate line 225 and overlaps a portion of the third extending portion 46. The second overlapping portion 48 corresponds to a portion of the first light blocking portion 237 that is outside a side edge of the gate line 225 and overlaps the third extending portion 46. With such a configuration, compared to the first extending portion 42 of the first embodiment (refer to FIG. 10), the third extending portion 46 extends straight along the Y-axis direction and therefore, the area of overlapping portions of the third extending portion 46 and the first light blocking portion 237 is smaller. Since the first resistance lowered section 238A, which is a portion ranging from the first end portion of the resistance lowered section 238 to the gate line 225, is charged at a same potential as the source line 226, the parasitic capacity created between the source line 226 and the first light blocking portion 237 can be reduced and a load on the source line 226 can be further reduced.

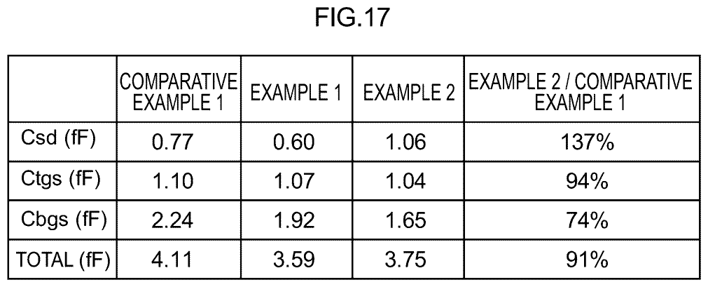

Next, to testify the advantageous effects of the array substrate of this embodiment, Comparative Experiment 2 was performed. In Comparative Experiment 2, parasitic capacitance (electrostatic capacitance) related to the source line 226 was calculated with using Example 2 described below. The array substrate of Example 2 has the configuration as previously described. Similar to Example 1 and Comparative Example 1 of Comparative Experiment 1, the resolution (pixel density) is 1728 ppi and the interval between the pixels is 14.7 μm in Example 2. In Comparative Experiment 2, with respect to Example 2, the parasitic capacitance Csd created between the source line 226 and the pixel electrode 228, the parasitic capacitance Ctgs created between the source line 226 and the gate line 225, and the parasitic capacitance Cbgs created between the source line 226 and the first light blocking portion 237 were calculated. The calculation results of the parasitic capacitances Csd, Ctgs, Cbgs are illustrated in FIG. 17. In FIG. 17, in addition to the calculation results of Example 2, the experiment results of Comparative Experiment 1 (the calculation results of Example 1 and Comparative Example 1) are illustrated. A unit of the parasitic capacitances Csd, Ctgs, Cbgs is fF. In addition to the calculation results of the parasitic capacitances Csd, Ctgs, Cbgs, ratios obtained by dividing the parasitic capacitances Csd, Ctgs, Cbgs of Example 2 by the parasitic capacitances Csd, Ctgs, Cbgs of Comparative Example 1, respectively, are illustrated with percentages in FIG. 17.

Experiment results of Comparative Experiment 2 will be described. With reference to FIG. 17, the parasitic capacitances Ctgs, Cbgs of Example 2 are lower than those of Comparative Example 1 and the parasitic capacitance Csd of Example 2 is higher than that of Comparative Example 1. This is presumably caused due to the following reasons. In Example 2, most portion of the second resistance lowered section 238B of the semiconductor section 227D that includes the second end portion of the semiconductor section 227D and is charged at the same potential as the drain electrode 227C overlaps the source line 226 and the overlapping area is larger than that of Example 1 and Comparative Example 1. On the other hand, the parasitic capacitances Ctgs, Cbgs of Example 2 are lower than those of Example 1. The reason why the parasitic capacitance Ctgs of Example 2 is lower than that of Example 1 may be presumed because the area of overlapping portions of the first resistance lowered section 238A and the gate line 225 is smaller than that of Example 1. The first resistance lowered section 238A corresponds to a portion of the semiconductor section 227D that includes the first end portion of the semiconductor section 227D and is charged at the same potential as the source line electrode 227B. The reason why the parasitic capacitance Cbgs of Example 2 is lower than that of Example 1 may be presumed because the area of overlapping portions of the first resistance lowered section 238A and the first light blocking portion 237 is smaller than that of Example 1. The first resistance lowered section 238A corresponds to a portion of the semiconductor section 227D that includes the first end portion of the semiconductor section 227D and is charged at the same potential as the source line electrode 227B.

As previously described, according to this embodiment, the semiconductor section 227D includes the third extending portion 46 that extends along the source line 226 with overlapping the source line 226 and crosses the gate line 225. The first overlapping portion 243 is a portion of the third extending portion 46. The third extending portion 46, which includes the first overlapping portion 243, extends along the source line 226 and is disposed to overlap the source line 226. Therefore, the area of overlapping portions of the semiconductor section 227D and the gate line 225 (the gate electrode 227A) is smaller compared to the overlapping area in the configuration in which the third extending portion extends obliquely with respect to the gate line 225 and the source line 226. Therefore, the parasitic capacitance created between the portion of the resistance lowered section 238 ranging from the first end portion of the resistance lowered section 238 to the gate line 225 and the gate line 225 can be reduced. Since the portion of the resistance lowered section 238 ranging from the first end portion of the resistance lowered section 238 to the gate line 225 is charged at the same potential as the source electrode 227B, the parasitic capacitance created between the gate line 225 and the source line 226 is reduced and a load on the source line 226 can be further reduced.

The array substrate of this embodiment includes the first light blocking portions 237. The first light blocking portion 237 extends along the gate line 225 with overlapping the gate line 225 and is wider than the gate line 225. The first light blocking portion 237 includes the second overlapping portion 48 that does not overlap the gate line 225 and overlaps a portion of the third extending portion 46. With the first light blocking portion 237 being wider than the gate line 225, light that travels toward the overlapping portion of the semiconductor section 227D that overlaps the gate electrode 227A can be effectively blocked. The first light blocking portion 237, which is wider than the gate line 225, includes the second overlapping portion 48 that does not overlap the gate line 225 and overlaps the third extending portion 46. Therefore, the area of overlapping portions of the third extending portion 46 and the first light blocking portion 237 is smaller compared to the overlapping area in the configuration in which the third extending portion extends obliquely with respect to the gate line 225 and the source line 226. Since the portion of the resistance lowered section 238 ranging from the first end portion of the resistance lowered section 238 to the gate line 225 is charged at the same potential as the source line 226, the parasitic capacitance created between the source line 226 and the first light blocking portion 237 is reduced and a load on the source line 226 can be further reduced.

### Other Embodiments

The technology described herein is not limited to the embodiments described above and illustrated by the drawings. For example, the following embodiments will be included in the technical scope of the present technology.

(1) In the first embodiment and the second embodiment, the inclination angle at which the first extending portion 42 is inclined with respect to the Y-axis direction may be altered from those illustrated in the drawings.

(2) In the first embodiment and the second embodiment, the length of the second extending portion 44 measured in the Y-axis direction may be altered from those illustrated in the drawings.

(3) Other than the configurations described in (1), (2), the planar shape of the semiconductor section 27D, 227D may be altered as appropriate other than those illustrated in the drawings. The planar shape of the gate lines 25, 225, the source lines 26, 126, 226, the drain electrodes 27C, 127C, 227C, the pixel electrodes 28, 128, 228, and the first light blocking portions 37, 237 may be altered as appropriate other than those illustrated in the drawings.

(4) In the configuration of each of the first embodiment and the third embodiment, the second light blocking portion 140 described in the second embodiment may be additionally included. In such a configuration, the opposed substrate 20 may not include the second light blocking portion 40.

(5) The configuration (the semiconductor section 227D) of the third embodiment may be combined with the configuration (the COA structure) of the second embodiment.

(6) The second light blocking portion 40 may be formed in a grid in a plan view so as to overlap the gate lines 25, 225 and the source lines 26, 126, 226.

(7) In the configuration of the second embodiment, the length of the second light blocking portion 140 measured in the Y-axis direction may be substantially same as that of the pixel electrode 28, 128, 228 and the second light blocking portions 140 may be arranged at intervals in the Y-axis direction. In such a configuration, the second light blocking portions 140 are arranged in the Y-axis direction at substantially same intervals as the pixel electrodes 28, 128, 228 are arranged in the Y-axis direction.

(8) The array substrate 21, 121 may include bumps that are higher than the surroundings at the positions of the first planarization film 35, 135 overlapping the spacers.

(9) A source driver may be disposed on the array substrate 21, 121 instead of the first circuit 14A.

(10) A source driver may be disposed on the flexible board 13 instead of the first circuit 14A.

(11) A gate driver may be disposed on the array substrate 21, 121 instead of the second circuit 14B.

(12) The materials, the thicknesses, and the layer structure (a single-layer film, a multilayer film) of the metal film, the semiconductor film, the insulation film, and the transparent electrode film may be altered as appropriate.

(13) The opposed substrate 20 may include an overcoat film for planarization.

(14) Organic material having negative type photosensitive properties may be used for the first planarization film 35, 135.

(15) The drain electrodes 27C, 127C, 227C may be made of a metal film. In such a configuration, the metal film may be used instead of the first transparent electrode film and subjected to patterning.

(16) The number of colors of the color filters 29, 129 may be four or more. A yellow filter that exhibits yellow or a transparent color filter through which light in all wavelength region can transmit may be additionally included.

(17) The TFTs 27 may not be top-gate type TFTs but may be bottom-gate type TFTs.

(18) With respect to the pixel electrodes 28, 128, 228 and the common electrode 30, 130, the pixel electrodes 28, 128, 228 may be defined as the upper electrode that is included in an upper layer and the common electrode 30, 130 may be defined as the lower electrode that is included in a lower layer. In such a configuration, the pixel electrodes 28, 128, 228, which are defined as the upper electrode, include slits.

(19) The alignment film may be subjected to orientation treatment with rubbing.

(20) The semiconductor film may be an amorphous silicon thin film or a polycrystalline silicon thin film.

(21) The operation mode of the liquid crystal panel 11, 111 may not be the FFS mode but may be the IPS mode.

(22) The liquid crystal panel 11, 111 may not be a transmissive type but may be a reflective type or a semi-transmissive type. With the liquid crystal panel 11, 111 being a reflective type, the backlight 12 is not necessary.

(23) Other than the head-mounted display 10HMD, a head-up display or a projector may be used as a device for magnifying images displayed on the liquid crystal panel 11, 111 using a lens. The present technology may be applied to a display device without having a magnifying display function (such as television devices, tablet-type terminals, and smartphones).

1. An array substrate comprising:
a first line;
a second line that crosses the first line;
a semiconductor section being made of semiconductor material, extending to cross the first line, and including a first end portion that overlaps the second line and a second end portion;
a first insulation film disposed between the first line and the semiconductor section;
a first electrode that is a portion of the first line and overlaps the semiconductor section via the first insulation film;
a second electrode that is a portion of the second line and overlaps the semiconductor section and is connected to the semiconductor section; and
a third electrode that is disposed to overlap the second end portion of the semiconductor section and connected to the semiconductor section, wherein
the semiconductor section includes a resistance lowered section that does not overlap the first electrode and in which resistance is lowered, and
the semiconductor section includes a first overlapping portion that overlaps a portion of the first electrode and a portion of the second line.

2. The array substrate according to claim 1, wherein
the semiconductor section includes a first extending portion that extends in an oblique direction with respect to the first line and the second line and crosses the first line, and
the first overlapping portion is a portion of the first extending portion.

3. The array substrate according to claim 2, wherein
the semiconductor section includes a second extending portion that includes the first end portion of the semiconductor section and extends parallel to the second line, and
the second extending portion is continuous to the first extending portion and overlaps the second line.

4. The array substrate according to claim 2, wherein the resistance lowered section of the semiconductor section includes a portion that ranges from the second end portion to the first line and does not overlap the second line.

5. The array substrate according to claim 1, wherein
the semiconductor section includes a third extending portion that extends along the second line and overlaps the second line and crosses the first line, and
the first overlapping portion is a portion of the third extending portion.

6. The array substrate according to claim 5, further comprising a first light blocking portion that extends along the first line and overlaps the first line and is wider than the first line,
the first light blocking portion including a second overlapping portion that does not overlap the first line and overlaps a portion of the third extending portion.

7. A display device comprising:
the array substrate according to claim 1; and
an opposed substrate disposed to opposite the array substrate.
